(19) United States
(12) Patent Application Publication
(10) Pub. No.: US 2026/0164942 A1
(43) Pub. Date: Jun. 11, 2026

(54) DISPLAY DEVICE

(71) Applicant: LG Display Co., Ltd., Seoul (KR)

(72) Inventors: Seyeon JUNG, Goyang-si (KR); JeongOh KIM, Uiwang-si (KR); HyunTaek LIM, Goyang-si (KR); Jaechoul YU, Paju-si (KR); Geumyoung LEE, Gimpo-si (KR)

(73) Assignee: LG Display Co., Ltd., Seoul (KR)

(21) Appl. No.: 19/371,604

(22) Filed: Oct. 28, 2025

(30) Foreign Application Priority Data
Dec. 6, 2024 (KR) 10-2024-0180575

(51) Int. Cl. H10K 59/122; H10K 59/80

(52) U.S. Cl. CPC H10K 59/122; H10K 59/878

(57) ABSTRACT

The display device includes a substrate, a plurality of sub pixels, a planarization layer which is disposed on the substrate and includes a concave portion and a protruding portion, a first electrode disposed so as to cover the concave portion and a part of the protruding portion, a reflection assistance layer which is disposed in a part of the concave portion and covers at least a part of an edge of the first electrode, a bank which is disposed on a part of a top surface of the first electrode and is disposed on the reflection assistance layer, an organic layer disposed on the top surface of the first electrode, and a second electrode disposed on the bank and the organic layer, so that to improve front brightness, viewing angle brightness and viewing angle stain reduction effects.

### CROSS-REFERENCE TO RELATED APPLICATIONS

This application claims the benefit of and priority to Korean Patent Application No. 10-2024-0180575 filed on Dec. 6, 2024, in the Korean Intellectual Property Office, the entire contents of which are incorporated herein by reference for all purposes.

### BACKGROUND

### 1. Technical Field

The present disclosure relates to a display device, and particularly to, for example, without limitation, a display device which improves a light extraction efficiency.

### 2. Description of Related Art

Currently, as it enters a full-scale information era, a field of a display device which visually expresses electrical information signals has been rapidly developed and studies are continued to improve performances of various display devices such as a thin-thickness, a light weight, and low power consumption.

Among various display devices, an organic light emitting display device is a self-emitting display device so that a separate light source is not necessary, which is different from the liquid crystal display device. Therefore, the organic light emitting display device may be manufactured to have a light weight and a small thickness. Further, since the display device is driven at a low voltage so that it is advantageous not only in terms of power consumption, but also in terms of color implementation, a response speed, a viewing angle, and a contrast ratio (CR). Therefore, it is expected to be utilized in various fields.

The description of related art should not be considered prior art merely because it is mentioned in or associated with this section. The description of related art includes information that describes one or more aspects of the subject technology, and the description in this section does not limit the scope of the invention.

### SUMMARY

An aspect to be achieved by the present disclosure is to provide a display device with a structure which improves a light extraction efficiency.

Another aspect to be achieved by the present disclosure is to provide a display device in which a front luminance and a viewing angle luminance are improved.

An aspect to be achieved by the present disclosure is to provide a display device which reduces recognition of a viewing angle spot.

Aspects of the present disclosure are not limited to the above-mentioned aspects, and other aspects, which are not mentioned above, can be clearly understood by those skilled in the art from the following descriptions.

According to an aspect of the present disclosure, there is provided a display device. The display device includes a substrate and a plurality of sub pixels. The display device further includes a planarization layer which is disposed on the substrate and includes a concave portion and a protruding portion. The display device further includes a first electrode disposed so as to cover the concave portion and a part of the protruding portion. The display device further includes a reflection assistance layer which is disposed in a part of the concave portion and covers at least a part of an edge of the first electrode. The display device further includes a bank which is disposed on a part of a top surface of the first electrode and is disposed on the reflection assistance layer. The display device further includes an organic layer disposed on the top surface of the first electrode. The display device further includes a second electrode disposed on the bank and the organic layer.

According to another aspect of the present disclosure, there is provided a display device. The display device includes a substrate and a plurality of sub pixels. The display device further includes a planarization layer which is disposed on the substrate and includes a concave portion and a protruding portion. The display device further includes a first electrode disposed so as to cover the concave portion and a part of the protruding portion. The display device further includes a reflection assistance layer which covers at least a part of an edge of the first electrode. The display device further includes a bank which is disposed on a part of a top surface of the first electrode and is disposed on the reflection assistance layer. The display device further includes an organic layer disposed on the top surface of the first electrode. The display device further includes a second electrode disposed on the bank and the organic layer. Further, at least one of the plurality of sub pixels includes a first emission area, a second emission area which encloses the first emission area, and a third emission area which encloses the second emission area and the reflection assistance layer is disposed in at least a part of each of the second emission area and the third emission area.

Other detailed matters of the example embodiments are included in the detailed description and the drawings.

According to the example embodiment of the present disclosure, a planarization layer includes an opening so as to correspond to an emission area to improve the light extraction efficiency so that the display device is driven at a low power in terms of power consumption reduction.

According to the example embodiment of the present disclosure, a reflection assistance layer is disposed in a part of a top surface of the first electrode disposed in a partial area of an opening and a protrusion of the planarization layer to improve the front luminance and the viewing angle luminance and reduce a viewing angle spot.

The effects of the present disclosure are not limited to the aforementioned effects, and other effects, which are not mentioned above, will be apparently understood to a person having ordinary skill in the art from the following description.

The aspects to be achieved by the present disclosure, the means for achieving the aspects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a perspective view of a display device according to an example embodiment of the present disclosure;

FIG. 2 is a view schematically illustrating an emission area and a non-emission area included in an active area of a display device according to an example embodiment of the present disclosure;

FIG. 3 is a plan view schematically illustrating one sub pixel structure disposed in an active area of a display device according to an example embodiment of the present disclosure;

FIG. 4 is a cross-sectional view of a display device taken along the line A-B of FIG. 3;

FIG. 5 is an enlarged view of an area X of FIG. 4;

FIGS. 6A to 6C are graphs for comparing a reflectance of a first electrode according to Comparative Embodiment 1 and a reflectance of a structure in which a first electrode according to Example Embodiment 1 and a reflection assistance layer are coupled;

FIG. 7 is a view schematically illustrating a laminated structure of a first electrode of a light emitting diode and a reflection assistance layer included in a display device according to an example embodiment of the present disclosure;

FIG. 8 is a graph obtained by measuring a reflectance of a second sub electrode according to a thickness of a third sub electrode;

FIGS. 9A and 9B are graphs illustrating a reflectance for a wavelength according to a thickness of a reflection assistance layer disposed in an active area of a display device according to an example embodiment of the present disclosure;

FIG. 10 is a plan view schematically illustrating one sub pixel structure disposed in an active area of a display device according to another example embodiment of the present disclosure;

FIG. 11 is a cross-sectional view taken along the line C-D of FIG. 10;

FIG. 12 is a graph comparing a viewing angle characteristic of display devices according to Comparative Embodiment 2 and Example Embodiment 2;

FIGS. 13 to 15 are schematic cross-sectional views illustrating a position and a shape of a structure which overlaps at least a part of a concave portion of a third planarization layer;

FIG. 16 is a plan view schematically illustrating one sub pixel structure disposed in an active area of a display device according to still another example embodiment of the present disclosure;

FIG. 17 is a cross-sectional view taken along the line E-F of FIG. 16;

FIG. 18 is a cross-sectional view illustrating one sub pixel structure disposed in an active area of a display device according to still another example embodiment of the present disclosure;

FIG. 19 is a cross-sectional view illustrating a plurality of sub pixel structures disposed in an active area of a display device according to still another example embodiment of the present disclosure;

FIG. 20A is a graph comparing a reflectance of a blue wavelength band of a display device according to Comparative Embodiment 3 and a reflectance of a blue wavelength band of a display device according to Example Embodiment 3;

FIG. 20B is a graph comparing a reflectance of a green wavelength band of a display device according to Comparative Embodiment 3 and a reflectance of a green wavelength band of a display device according to Example Embodiment 3; and

FIG. 20C is a graph comparing a reflectance of a red wavelength band of a display device according to Comparative Embodiment 3 and a reflectance of a red wavelength band of a display device according to Example Embodiment 3.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

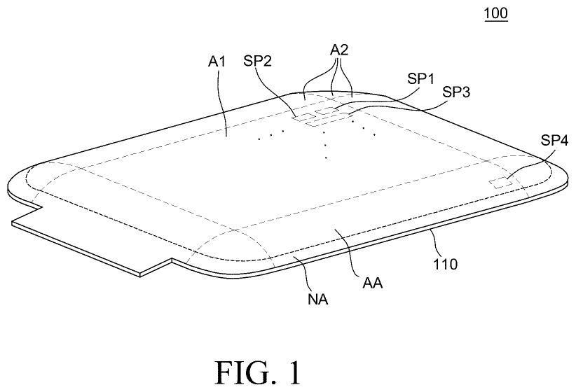

FIG. 1 is a perspective view of a display device according to an example embodiment of the present disclosure.

Referring to FIG. 1, a display device 100 may include a substrate 110. The substrate 110 may support and protect various components of the display device 100.

The substrate 110 includes a first area A1 and a second area A2. The first area A1 may be a flat area and the second area A2 may be a curved area. The first area A1 may be referred to as a flat portion and the second area A2 may be referred to as a curved portion or a bent portion.

The second area A2 is disposed in an upper portion, a lower portion, and both side portions of the first area A1 so that the farther from the first area A1, the larger the gradient, but is not limited thereto. For example, each of the second areas A2 disposed in the upper portion, the lower portion, and both side portions of the first area A1 may be disposed with different curvatures.

Further, the second area A2 may be disposed on only one side of the first area A1 or may be disposed on all sides of the first area A1. For example, when the first area A1 has four sides, the second area A2 may be disposed in one or more sides, among four sides, or as illustrated in FIG. 1, may be disposed in all the sides, but is not limited thereto.

The display device 100 includes an active area AA and a non-active area NA.

The active area AA and the non-active area NA may be disposed in the first area A1 and the second area A2 of the substrate 110, respectively.

The active area AA is an area in which an image is displayed in the display device 100 and a display element and various driving elements for driving the display element may be disposed in the active area AA.

A plurality of sub pixels SP1, SP2, SP3, and SP4 may be included in the active area AA. The sub pixel SP is a minimum unit which configures a screen and each of the plurality of sub pixels SP1, SP2, SP3, and SP4 may include a light emitting diode and a driving circuit.

The plurality of sub pixels SP1, SP2, SP3, and SP4 may include a first sub pixel SP1, a second sub pixel SP2, a third sub pixel SP3, and a fourth sub pixel SP4.

The first to third sub pixels SP1, SP2, and SP3 are sub pixels disposed in the first area A1 of the active area AA and the fourth sub pixel SP4 is a sub pixel disposed in the second area A2 of the active area AA. That is, the first to third sub pixels SP1, SP2, and SP3 may be disposed in the flat portion of the substrate 110 and the fourth sub pixel SP4 may be disposed in a curved portion of the substrate 110.

The first to fourth sub pixels SP1, SP2, SP3, and SP4 disposed in the active area AA may include different areas and shapes, but are not limited thereto. In some cases, the first to fourth sub pixels SP1, SP2, SP3, and SP4 may have the same area and shape.

The non-active area NA is an area where no image is displayed and various components for driving the plurality of sub pixels SP1, SP2, SP3, and SP4 disposed in the active area AA may be disposed in the non-active area NA. For example, a driving IC which supplies a signal for driving the plurality of sub pixels SP1, SP2, SP3, and SP4, a flexible film, and a pad for being connected thereto may be disposed.

The non-active area NA is an area which encloses the active area AA, but is not limited thereto. For example, the non-active area NA may be an area extending from one side of the active area AA.

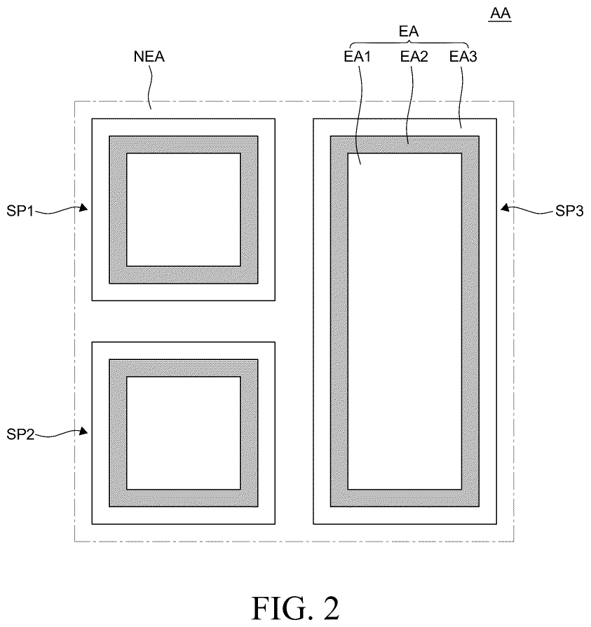

FIG. 2 is a view schematically illustrating an emission area and a non-emission area included in an active area of a display device according to an example embodiment of the present disclosure.

Referring to FIG. 2, the active area AA of the display device 100 may include a plurality of sub pixels SP1, SP2, SP3, and SP4.

At least one sub pixel SP, among the plurality of sub pixels SP1, SP2, SP3, and SP4 disposed in the active area AA, may include an emission area EA and a non-emission area NEA which encloses the emission area EA.

At least one emission area EA may include a plurality of emission areas EA1, EA2, and EA3. For example, the emission area EA may include a first emission area EA1, a second emission area EA2, and a third emission area EA3.

Further, the second emission area EA2 may be disposed so as to enclose the first emission area EA1. The third emission area EA3 may be disposed so as to enclose the second emission area EA2.

A luminance of the second emission area EA2 may be lower than a luminance of the first emission area EA1 and a luminance of a third emission area EA3. A luminance of the third emission area EA3 may be lower than a luminance of the first emission area EA1.

A non-emission area NEA may be disposed between emission areas EA of the plurality of sub pixels SP1, SP2, SP3, and SP4.

The non-emission area NEA may be disposed so as to enclose the third emission area EA3 of each sub pixel.

Even though in FIG. 2, the emission areas EA of the first to third sub pixels SP1, SP2, and SP3 include first to third emission areas EA1, EA2, and EA3, but the present disclosure is not limited thereto.

For example, at least one sub pixel of the first to third sub pixels SP1, SP2, and SP3 may include only one emission area. Alternatively, the fourth sub pixel SP4 disposed in the second area A2 of the display device 100 may also have a structure in which the emission area EA includes the first to third emission areas EA1, EA2, and EA3.

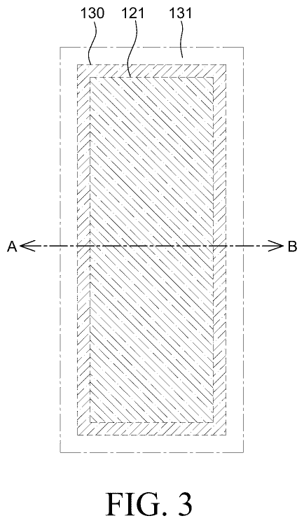

FIG. 3 is a plan view schematically illustrating one sub pixel structure disposed in an active area of a display device according to an example embodiment of the present disclosure.

Referring to FIG. 3, at least one sub pixel of the display device 100 which is disposed in the active area AA may include a first electrode 121 of a light emitting diode, a reflection assistance layer 130, and a bank 131.

Each of the reflection assistance layer 130 and the bank 131 may be disposed so as to expose a part of the top surface of the first electrode 121.

The reflection assistance layer 130 and the bank 131 may cover an edge of the first electrode 131.

The bank 131 may overlap the entire reflection assistance layer 130. Further, the bank 131 may cover an edge of the reflection assistance layer 130. That is, the bank 131 may be disposed so as to cover a top surface and a side surface of the reflection assistance layer 130.

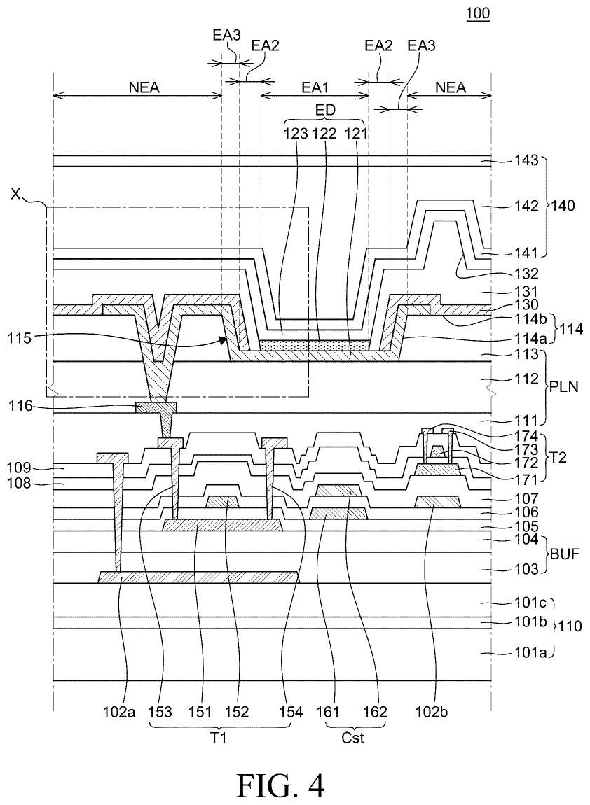

A placement relationship of a first electrode 121 of a light emitting diode, a reflection assistance layer 130, and a bank 131 will be specifically described with reference to FIG. 4.

FIG. 4 is a cross-sectional view of a display device taken along the line A-B of FIG. 3.

Referring to FIG. 4, the substrate 110 may include a first substrate 101a, a second substrate 101c, and an intermediate film 101b between the first substrate 101a and the second substrate 101c.

Each of the first substrate 101a and the second substrate 101c may be formed of a glass or a plastic material having a flexibility. When the first substrate 101a and the second substrate 101c are formed of a plastic material, for example, the first substrate 101a and the second substrate 101c may be formed of polyimide (PI), but it is not limited thereto.

The intermediate film 101b may be an inorganic film and suppress permeation of moisture, but is not limited thereto.

A first buffer layer BUF may be disposed on the substrate 110. The buffer layer 111 may improve adhesive strength between layers formed on the buffer layer 111 and the substrate 110 and block alkali components leaked from the substrate 110.

The first buffer layer BUF may be a single layer or a multi-layer. When the first buffer layer BUF is a multi-layer, the first buffer layer BUF may include a multi-buffer layer 103 and an active buffer layer 104.

The multi-buffer layer 103 and the active buffer layer 104 may be formed of a single layer of silicon nitride (SiNx) or silicon oxide (SiOx) or a multi-layer of silicon nitride (SiNx) and silicon oxide (SiOx), but are not limited thereto.

The first buffer layer BUF may be omitted based on a type or a material of the substrate 110 and a structure and a type of the thin film transistor 120.

A first light blocking layer 102a may be disposed between the first buffer BUF and the substrate 110.

The first light blocking layer 102a may overlap all or a part of the first active layer 151. The first light blocking layer 102a may serve as a light shield which blocks light entering from the lower portion. In this case, the first light blocking layer 102a may be electrically connected to a first source electrode 153.

The first light blocking layer 102a may include a conductive material. For example, the first light blocking layer 102a may be any one of molybdenum (Mo), aluminum (Al), chrome (Cr), gold (Au), titanium (Ti), nickel (Ni), neodymium (Nd), and copper (Cu) or an alloy of two or more of them, or a multi-layer thereof, but it is not limited thereto.

A plurality of transistors T1 and T2, a storage capacitor Cst, and various electrodes or signal lines may be disposed on the first buffer layer BUF.

For example, the plurality of transistors T1 and T2 formed on the first buffer layer BUF may be configured by the same material and may be disposed on the same layer. In contrast, as illustrated in FIG. 4, a first transistor T1 and a second transistor T2, among the plurality of transistors T1 and T2, may be configured by different materials and located on different layers.

The plurality of transistors T1 and T2 may include the first transistor T1 and the second transistor T2.

The first transistor T1 may include a first active layer 151, a first gate electrode 152, a first source electrode 153, and a first drain electrode 154.

The second transistor T2 may include a second active layer 171, a second gate electrode 172, a second source electrode 174, and a second drain electrode 173.

The second active layer 171 of the second transistor T2 may be located to be higher than the first active layer 151 of the first transistor T1.

The first buffer layer BUF may be disposed below the first active layer 151 of the first transistor T1 and a second buffer layer 107 may be disposed below the second active layer 171 of the second transistor T2.

A second light blocking layer 102b may be disposed below the second active layer 171.

The second light blocking layer 102b may include a conductive material. For example, the first light blocking layer 102a may be any one of molybdenum (Mo), aluminum (Al), chrome (Cr), gold (Au), titanium (Ti), nickel (Ni), neodymium (Nd), and copper (Cu) or an alloy of two or more of them, or a multi-layer thereof, but it is not limited thereto.

The first active layer 151 of the first transistor T1 may be disposed on the first buffer layer BUF and the second active layer 171 of the second transistor T2 may be disposed on the second buffer layer 107. Here, the second buffer layer 107 may be located to be higher than the first buffer layer BUF.

The first active layer 151 of the first transistor T1 may be disposed on the first buffer layer BUF and a first gate insulating film 105 may be disposed on the first active layer 151 of the first transistor T1.

The first active layer 151 may be formed of an oxide semiconductor or amorphous silicon (a-Si), polycrystalline silicon (poly-Si), or an organic semiconductor.

The first gate insulating film 105 may be formed as a single layer of silicon nitride (SiNx) or silicon oxide (SiOx) which is an inorganic material or a multi-layer of silicon nitride (SiNx) or silicon oxide (SiOx), but it is not limited thereto.

The second gate electrode 172 of the second transistor T2 may be disposed on the first gate insulating film 105 and a first interlayer insulating film 106 may be disposed on the second gate electrode 172 of the second transistor T2.

The second gate electrode 172 may be any one of molybdenum (Mo), aluminum (Al), chrome (Cr), gold (Au), titanium (Ti), nickel (Ni), neodymium (Nd), and copper (Cu) or an alloy of two or more of them, or a multi-layer thereof, but it is not limited thereto.

The first interlayer insulating film 106 may be configured as a single layer of silicon nitride (SiNx) or silicon oxide (SiOx) which is an inorganic material or a multi-layer of silicon nitride (SiNx) or silicon oxide (SiOx), but it is not limited thereto.

The first active layer 151 of the first transistor T1 may include a first channel region overlapping the first gate electrode 152, a first source connection region located on one side of the first channel region, and a first drain connection region located on the other side of the first channel region.

The second buffer layer 107 may be disposed on the first interlayer insulating film 106.

The second buffer layer 107 may be configured as a single layer of silicon nitride (SiNx) or silicon oxide (SiOx) which is an inorganic material or a multi-layer of silicon nitride (SiNx) or silicon oxide (SiOx), but it is not limited thereto.

The second active layer 171 of the second transistor T2 may be disposed on the second buffer layer 107 and the second gate insulating film 108 may be disposed on the second active layer 171.

The second active layer 171 may be formed of an oxide semiconductor or amorphous silicon (a-Si), polycrystalline silicon (poly-Si), or an organic semiconductor.

The second gate insulating film 108 may be formed as a single layer of silicon nitride (SiNx) or silicon oxide (SiOx) which is an inorganic material or a multi-layer of silicon nitride (SiNx) or silicon oxide (SiOx), but it is not limited thereto.

The second gate electrode 172 of the second transistor T2 may be disposed on the second gate insulating film 108 and a second interlayer insulating film 109 may be disposed on the second gate electrode 172.

The second gate electrode 172 may be any one of molybdenum (Mo), aluminum (Al), chrome (Cr), gold (Au), titanium (Ti), nickel (Ni), neodymium (Nd), and copper (Cu) or an alloy of two or more of them, or a multi-layer thereof, but it is not limited thereto.

The second interlayer insulating film 109 may be configured as a single layer of silicon nitride (SiNx) or silicon oxide (SiOx) which is an inorganic material or a multi-layer of silicon nitride (SiNx) or silicon oxide (SiOx), but it is not limited thereto.

Here, the second active layer 171 of the second transistor T2 may include a second channel region overlapping the second gate electrode 172, a second source connection region located on one side of the second channel region, and a second drain connection region located on the other side of the second channel region.

The first source electrode 153 and the first drain electrode 154 of the first transistor T1 may be disposed on the second interlayer insulating film 109. Further, the second source electrode 174 and the second drain electrode 173 of the second transistor T2 may be disposed on the second interlayer insulating film 109.

The first source electrode 153 and the first drain electrode 154 of the first transistor T1 may be connected to the first source connection region and the first drain connection region of the first active layer 151 through contact holes of the second interlayer insulating film 109, the second gate insulating film 108, the second buffer layer 107, the first interlayer insulating film 106, and the first gate insulating film 105.

The second source electrode 174 and the second drain electrode 173 of the second transistor T2 may be connected to the second source connection region and the second drain connection region of the second active layer 171 through contact holes of the second interlayer insulating film 109 and the second gate insulating film 108.

The storage capacitor Cst may include a first capacitor electrode 161 and a second capacitor electrode 162.

The first source electrode 153, the first drain electrode 154, the second source electrode 174, the second drain electrode 173, the first capacitor electrode 161, and the second capacitor electrode 162 may be any one of molybdenum (Mo), aluminum (Al), chrome (Cr), gold (Au), titanium (Ti), nickel (Ni), neodymium (Nd), and copper (Cu) or an alloy of two or more of them, or a multi-layer thereof, but the present disclosure is not limited thereto.

A planarization layer may be disposed on the first transistor T1 and the second transistor T2.

The planarization layer PLN may include a first planarization layer 111, a second planarization layer 112, and a third planarization layer 113.

Each of the first to third planarization layers 111, 112, and 113 may be formed of one of acrylic resin, epoxy resin, phenol resin, polyamide resin, polyimide resin, unsaturated polyester resin, polyphenylene resin, polyphenylene sulfide resin, benzocyclobutene, and photoresist, but is not limited thereto.

The first planarization layer 111 may be disposed on the first transistor T1 and the second transistor T2. That is, the first planarization layer 111 may be disposed on the first source electrode 153 and the first drain electrode 173 of the first transistor T1 and the second source electrode 174 and the second drain electrode 173 of the second transistor T2.

A relay electrode 116 may be disposed on the first planarization layer 111. The relay electrode 116 may be an electrode which relays electrical connection between the first source electrode 153 of the first transistor T1 and the first electrode 121 of the light emitting diode ED.

The relay electrode 116 may be electrically connected to the first source electrode 153 of the first transistor T1 through a contact hole of the first planarization layer 111.

The relay electrode 116 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

The second planarization layer 112 may be disposed on the relay electrode 116 and the first planarization layer 111.

The third planarization layer 113 may be disposed on the second planarization layer 112. The first electrode 121 of the light emitting diode ED may be electrically connected to the relay electrode 116 through contact holes of the second planarization layer 112 and the third planarization layer 113.

Even though in FIG. 4, a structure in which the second planarization layer 112 is disposed on the first planarization layer 111 and the third planarization layer 113 is disposed on the second planarization layer 112 is illustrated, the present disclosure is not limited thereto. For example, on the substrate 110, the third planarization layer 113 may be disposed on the first planarization layer 111 or only the third planarization layer 113 may be disposed.

The third planarization layer 113 may include a protruding portion 114 and a concave portion 115.

The concave portion 115 of the third planarization layer 113 may expose a part of the top surface of the second planarization layer 112.

The concave portion 115 of the third planarization layer 113 may be disposed in an area corresponding to a first emission area EA1 and a second emission area EA2.

Even though in FIG. 4, a structure in which the third planarization layer 113 has the concave portion 115 in an area corresponding to the first and second emission areas EA1 and EA2 is illustrated, the present disclosure is not limited thereto. For example, a height of the third planarization layer 113 disposed in an area corresponding to the first and second emission areas EA1 and EA2 may be lower than a height of the third planarization layer 113 disposed in an area (excluding a contact hole area) corresponding to the non-emission area NEA and the third emission area EA3.

The protruding portion 114 of the third planarization layer 113 may include an inclined portion 114a and a flat portion 114b extending from the inclined portion 114a.

The first electrode 121 may be disposed in the concave portion 115 of the third planarization layer 113 and may be disposed in a partial area of the protruding portion 114. Specifically, the first electrode 114 may be disposed in the concave portion 115 and on the inclined portion 114a of the protruding portion 114, and may be disposed in a partial area on the flat portion 114b.

The first electrode 121 may be an anode electrode of the light emitting diode ED.

The first electrode 121 may include a reflection electrode which reflects light.

The first electrode 121 may be a single layer structure or a multi-layered structure. When the first electrode 121 is a multi-layered structure, the first electrode may include at least reflection electrode layer and at least one transparent conductive material layer.

The reflection electrode included in the first electrode 121 may include any one of metals, such as aluminum (Al), gold (Au), silver (Ag), copper (Cu), tungsten (W), molybdenum (Mo), chrome (Cr), tantalum (Ta), and titanium (Ti) or an alloy thereof, but is not limited thereto.

The transparent conductive material included in the first electrode 121 may include at least one of indium tin oxide (ITO), indium zinc oxide (IZO), or indium gallium zinc oxide (IGZO), but is not limited thereto.

The first electrode 121 may also be disposed in contact holes provided in the second planarization layer 112 and the third planarization layer 113.

The first electrode 121 may be in contact with a top surface of the second planarization layer 112 in an area corresponding to the concave portion 115 of the third planarization layer 113.

The first electrode 121 may be in contact with the relay electrode 116 disposed below the second planarization layer 112 through the contact holes provided in the second planarization layer 112 and the third planarization layer 113.

A reflection assistance layer 130 may be disposed on a part of the third planarization layer 113 and a part of the first electrode 121.

The reflection assistance layer 130 may be disposed so as to cover an edge of the first electrode 121 and extend to a part of the top surface of the third planarization layer 113.

The reflection assistance layer 130 may overlap a partial area of the concave portion 115 of the third planarization layer 113. Specifically, the reflection assistance layer 130 may be disposed on a side surface of the third planarization layer in the concave portion 115 of the third planarization layer 113 and may also be disposed in a part of the top surface of the first electrode 121.

The reflection assistance layer 130 may not overlap a part of the top surface of the first electrode 121 disposed in the concave portion 115 of the third planarization layer 113.

The reflection assistance layer 130 may also overlap the contact hole area. Specifically, the reflection assistance layer 130 may be disposed along the contact hole area disposed in the second planarization layer 112 and the third planarization layer 113. Here, the reflection assistance layer 130 may be disposed in the contact hole area formed in the second planarization layer 112 and the third planarization layer 113, but may be filled in a part in the contact hole, but may not be filled in the other part. That is, the reflection assistance layer 130 may be formed along shapes of the top surfaces of the first electrode 121 and the third planarization layer 113 disposed below the reflection assistance layer 130.

The bank 131 may be disposed above the reflection assistance layer 130. The bank 131 may include an organic material.

The bank 131 may be disposed while covering a top surface and a side surface of the reflection assistance layer 130.

The reflection assistance layer 130 may be patterned by an etching process.

For example, after forming a material of the reflection assistance layer 130 on the substrate 110 on which the first electrode 121 is disposed, a material of the bank 131 may be formed on the material of the reflection assistance layer 130.

After forming a hole of the bank 131 by patterning the material of the bank 131, the material of the reflection assistance layer 130 may be patterned with the patterned material of the bank 131 as a mask. At this time, an end of the material of the bank 131 and an end of the patterned reflection assistance layer 130 may match. Therefore, in order to allow the bank 131 to cover to the side surface of the reflection assistance layer 130, the material of the bank 131 may be thermally processed. The material of the bank 131 includes an organic material so that when heat is applied, a flowability may be exhibited. Therefore, the material of the bank 131 may flow so as to cover the side surface of the reflection assistance layer 130.

By this process, the bank 131 may be disposed while covering a top surface and a side surface of the reflection assistance layer 130.

The bank 131 may include a hole of the bank 131 which exposes a part of the top surface of the first electrode 121 in a partial area overlapping the concave portion 115 of the third planarization layer 113. The hole of the bank 131 may overlap a part of the first electrode 121.

The bank 131 may also overlap a part of the concave portion 115 of the third planarization layer 113. Specifically, the bank 131 may be disposed on a side surface of the third planarization layer 113 in the concave portion 115 of the third planarization layer 113 and may also be disposed in a part of the top surface of the first electrode 121.

The bank 131 overlaps also the contact hole area and may be filled in the contact hole area. Further, the bank 131 may overlap the first electrode 121 and the reflection assistance layer 130 in the contact hole area.

At least one spacer 132 which is integrally formed with the bank 131 may be disposed above the third planarization layer 113.

Even though in FIG. 4, a structure in which the spacer 132 is integrally formed with the bank 131 is illustrated, the present disclosure is not limited thereto. The spacer 132 may be separated from the bank 131.

The spacer 132 may overlap a part of the flat portion 114b of the protruding portion 114 of the third planarization layer 113. The spacer 132 may not overlap the concave portion 115 of the third planarization layer 113 and may not overlap the inclined portion 114a of the protruding portion 114 of the third planarization layer 113.

The organic layer 122 of the light emitting diode ED may be disposed in the concave portion 115 of the third planarization layer 113.

The organic layer 122 may include at least one emission layer and at least one common layer.

The emission layer is an organic layer which emits light with a specific color. Different emission layers may be disposed in the plurality of sub pixels SP1, SP2, SP3, and SP4 or the same emission layer may be disposed in all the plurality of sub pixels SP1, SP2, SP3, and SP4. For example, when different emission layers are disposed in the plurality of sub pixels SP1, SP2, SP3, and SP4, a red emission layer may be disposed in a red sub pixel, a green emission layer may be disposed in a green sub pixel, and a blue emission layer may be disposed in a blue sub pixel. When the same emission layer is disposed in all the plurality of sub pixels SP1, SP2, SP3, and SP4, light from the emission layer may be converted to various color light through a separate light conversion layer and a color filter.

The common layer is an organic layer which is disposed to improve luminous efficiency of the emission layer. The common layer may be formed as the same layer over the plurality of sub pixels SP1, SP2, SP3, and SP4. That is, the common layers of the plurality of sub pixels SP1, SP2, SP3, and SP4 may be simultaneously formed with the same material by the same process. The common layer may include a hole injection layer, a hole transport layer, an electron transport layer, an electron injection layer, and a charge generation layer, but is not limited thereto.

The organic layer 122 may be disposed on the top surface of the first electrode 121 which does not overlap the bank 131 in the concave portion 115 of the third planarization layer 113.

The organic layer 122 may be spaced apart from the reflection assistance layer 130 in the concave portion 115 of the third planarization layer 113. Specifically, the bank 131 may be disposed between the organic layer 122 and the reflection assistance layer 130 in the concave portion 115 of the third planarization layer 113.

The second electrode 123 of the light emitting diode ED may be disposed on the organic layer 122, the bank 131, the spacer 132. The second electrode 123 may be a cathode electrode of the light emitting diode ED.

The second electrode 123 may be formed of a transparent conductive material such as indium tin oxide (ITO) or indium zinc oxide (IZO), or a metal alloy such as MgAg or a ytterbium (Yb) alloy and may further include a metal doping layer, but is not limited thereto. An encapsulation layer 140 may be disposed on the second electrode 123 of the light emitting diode ED.

The encapsulation layer 140 may be disposed so as to cover the light emitting diodes ED.

The encapsulation layer 140 may be a layer which suppresses permeation of moisture or oxygen to the light emitting diode ED disposed below the encapsulation layer 140. Specifically, the encapsulation layer 140 may suppress permeation of moisture or oxygen to the organic layer 122 including an emission layer.

The encapsulation layer 140 may include a first encapsulation layer 141, a second encapsulation layer 142, and a third encapsulation layer 143.

The first encapsulation layer 141 may be disposed on the second electrode 123 of the light emitting diode ED, the second encapsulation layer 142 may be disposed on the first encapsulation layer 141, and the third encapsulation layer 143 may be disposed on the second encapsulation layer 142.

The first encapsulation layer 141 and the third encapsulation layer 143 may be inorganic films and the second encapsulation layer 142 may be an organic film. The second encapsulation layer 142 is configured by the organic film to serve as a planarization layer.

In the meantime, at least one sub pixel SP of the display device 100 may include a plurality of emission areas EA1, EA2, and EA3. For example, at least one sub pixel SP of the display device 100 may include a first emission area EA1, a second emission area EA2 enclosing the first emission area EA1, and a third emission area EA3 enclosing the second emission area EA2.

The first emission area EA1 may be an area in which the bank 131 is not disposed on the first electrode 121. That is, an area in which the hole of the bank 131 which exposes a part of the top surface of the first electrode 121 is located in the concave portion 115 of the third planarization layer 113 may be the first emission area EA1 of the sub pixel SP.

The second emission area EA2 may include an area in which the concave portion 115 of the third planarization layer 113 overlaps the bank 131.

The third emission layer EA3 may include an area corresponding to the inclined portion 114a of the protruding portion 114 of the third planarization layer 113. Alternatively, the third emission area EA3 may include an area in which the first electrode 121 is disposed on the inclined portion 114a.

The first electrode 121 of the light emitting diode ED may be disposed in the entire first to third emission areas EA1, EA2, and EA3 and may be disposed in a part of the non-emission area NEA. The organic layer 122 of the light emitting diode ED may be disposed in the first emission area EA1 and in some cases, may also be disposed in a part of the second emission area EA2.

The reflection assistance layer 130 may be disposed in at least a part of the second emission area EA2 and the entire third emission area EA3. Further, the reflection assistance layer 130 may be disposed in at least a part of the non-emission area NEA, but may not be disposed in the first emission area EA1.

The reflection assistance layer 130 is disposed in at least a part of the second emission area EA2 and the entire third emission area EA3 to improve the front luminance and the viewing angle characteristic.

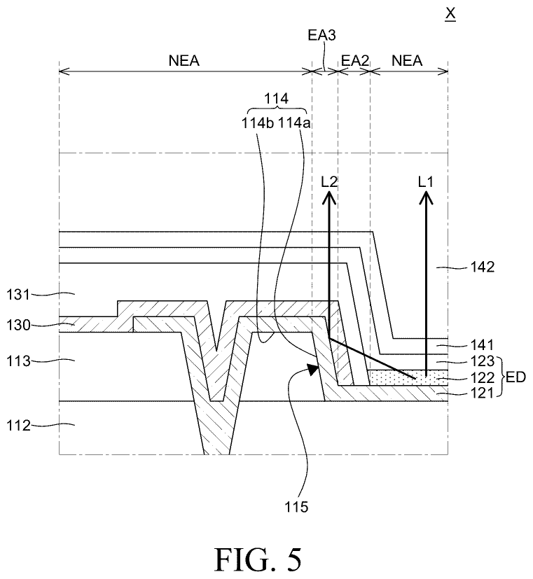

This will be described below in detail with reference to FIG. 5.

FIG. 5 is an enlarged view of an area X of FIG. 4.

Referring to FIG. 5, the display device 100 may include a light emitting diode ED and a reflection assistance layer 130.

The reflection assistance layer 130 may include a material having a resistance higher than a resistance of the first electrode 121 of the light emitting diode ED. The reflection assistance layer 130 may include an inorganic compound, but is not limited thereto.

Further, the reflection assistance layer 130 may include a material in which an amount of transmitted light is larger than an amount of absorbed light. For example, the reflection assistance layer 130 may include the material same as a material included in at least one layer when a plurality of organic layers 122 of the light emitting diode ED is formed. The reflection assistance layer 130 may include magnesium fluoride (MgF₂), but is not limited thereto.

The bank 131 may be disposed so as to enclose a top surface and a side surface of the reflection assistance layer 130. Therefore, the reflection assistance layer 130 may be disposed to be spaced apart from the organic layer 122 of the light emitting diode ED disposed in the concave portion 115 of the third planarization layer 113.

The reflection assistance layer 130 including an inorganic compound is spaced apart from the organic layer 122 to increase an area of the first emission area EA1.

Specifically, in a contact area of the reflection assistance layer 130 and the organic layer 122, the light is not emitted so that the area of the emission area may be reduced as much as the contact area of the reflection assistance layer 130 and the organic layer 122. Accordingly, the front and side luminous characteristics of the display device 100 may be degraded.

The entire surface of the reflection assistance layer 130 of the display device 100 according to the present disclosure may be enclosed by the bank 131 and is separated from the organic layer 122 by the bank 131 so that there may be no contact area of the reflection assistance layer 130 and the organic layer 122.

A part L1 of light emitted from the light emitting diode ED is released toward the second electrode 123 from the organic layer 122 to go to the outside of the display device 100.

The other part L2 of the light emitted from the light emitting diode ED passes through the bank 131 and the reflection assistance layer 130 disposed in the concave portion 115 of the third planarization layer 113 to reach the first electrode 121. The other part L2 of the light emitted from the light emitting diode ED is reflected by the first electrode 121 including a reflection electrode to be released to the outside of the display device 100. By doing this, the light extraction efficiency of the display device 100 may be improved.

The other part L2 of the light emitted from the light emitting diode ED passes through the bank 131 to reach the reflection assistance layer 130. Accordingly, the reflection assistance layer 130 may serve to reduce an amount of light which is irregularly reflected at the interface between the first electrode 121 and the reflection assistance layer 130 to be trapped without being released to the outside of the display device 100.

That is, the reflection assistance layer 130 serves to increase an amount of light which reaches the reflection electrode included in the first electrode 121 to increase an amount of light which is reflected from the first electrode 121 to be extracted to the outside of the display device 100 to improve the front luminance and the viewing angle luminance.

The other part L2 of the light emitted from the light emitting diode ED may be emitted to the third emission area EA3 or to the second emission area EA2. Further, in some cases, the other part L2 of light emitted from the light emitting diode ED may be emitted to the first emission area EA1.

When the light extraction efficiency is decreased, in order to increase the luminance of the display device 100, a high power consumption is requested. However, in the display device 100 according to the example embodiment of the present disclosure, the first electrode 121 of the light emitting diode ED disposed on the concave portion 115 and a part of the protruding portion 114 of the third planarization layer 113 improves the light extraction efficiency of the display device 100. Further, the reflection assistance layer 130 which overlaps an edge of the first electrode 121 increases an amount of light which is reflected from the first electrode 121 to be released to the outside of the display device 100. As a result, a light extraction efficiency for front and side surfaces of the display device 100 may be further improved.

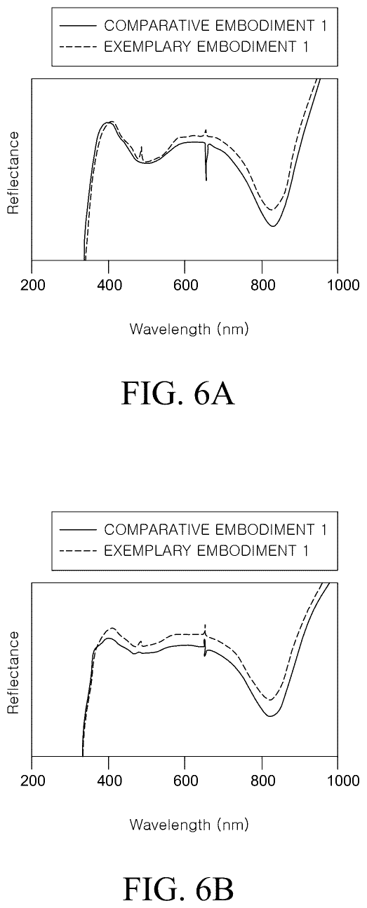

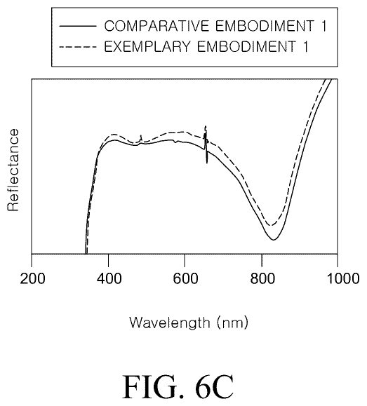

FIGS. 6A to 6C are graphs for comparing a reflectance of a first electrode according to Comparative Embodiment 1 and a reflectance of a structure in which a first electrode according to Example Embodiment 1 and a reflection assistance layer are coupled.

A reflection electrode of a first electrode according to Comparative Embodiment 1 of FIGS. 6A to 6C includes aluminum (Al) and a thickness of the reflection electrode is 150 nm. A reflection electrode of a first electrode according to Example Embodiment 1 of FIGS. 6A to 6C includes aluminum (Al), a thickness of the reflection electrode is 150 nm and a thickness of a reflection assistance layer disposed on the reflection electrode is 100 nm. A graph of FIG. 6 is obtained by measuring a reflectance for light having a visible wavelength at an angle of 30° to 60° for a front surface.

Referring to FIGS. 6A to 6C, it is understood that a structure in which a first electrode according to Example Embodiment 1 and a reflection assistance layer on the first electrode are disposed has a reflectance for light having a visible wavelength at 30° to 60° for a front surface, higher than that of the first electrode according to Comparative Embodiment 1.

Specifically, it is understood that at the angle of 30° to 60°, the structure in which a first electrode according to Example Embodiment 1 and a reflection assistance layer on the first electrode are disposed has a reflectance much higher than the first electrode according to Comparative Embodiment 1, from the wavelength of 550 nm or higher.

It is understood that at the angle of 45°, the structure in which a first electrode according to Example Embodiment 1 and a reflection assistance layer on the first electrode are disposed has a reflectance higher than the first electrode according to Comparative Embodiment 1, for the entire visible wavelengths.

That is, the reflection assistance layer 130 may increase an amount of light which reaches the reflection electrode of the first electrode 121 to increase an amount of light which is reflected by the reflection electrode of the first electrode 121.

Accordingly, the display device 100 including the reflection assistance layer 130 may increase not only the front luminance, but also the side luminance (or a viewing angle luminance). Further, even though the display device 100 is seen in a specific direction, a viewing angle spot which is seen as a spot due to the low luminance may be suppressed.

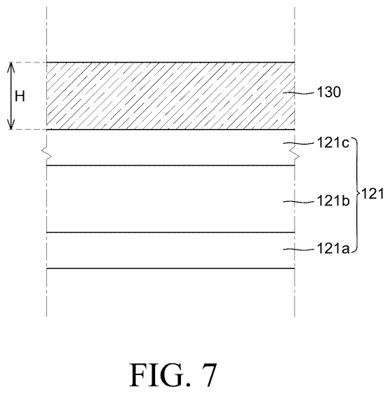

FIG. 7 is a view schematically illustrating a lamination structure of a first electrode of a light emitting diode and a reflection assistance layer included in a display device according to an example embodiment of the present disclosure.

Referring to FIG. 7, the reflection assistance layer 130 may be disposed in at least a part of the first electrode 121 of the light emitting diode ED.

The first electrode 121 of the light emitting diode ED may be formed with a multi-layered structure. The first electrode 121 may include a first sub electrode 121a, a second sub electrode 121b disposed on the first sub electrode 121a, and a third sub electrode 121c disposed on the second sub electrode 121b.

The first sub electrode 121a and the third sub electrode 121c may include the same material.

For example, the first sub electrode 121a and the third sub electrode 121c may include a transparent conductive material. The first sub electrode 121a and the third sub electrode 121c may include at least one of indium tin oxide (ITO), indium zinc oxide (IZO), or indium gallium zinc oxide (IGZO), but are not limited thereto.

The second sub electrode 121b may include a reflective conductive material. For example, the second sub electrode 121b may include any one of metals, such as aluminum (Al), gold (Au), silver (Ag), copper (Cu), tungsten (W), molybdenum (Mo), chrome (Cr), tantalum (Ta), and titanium (Ti) or an alloy thereof, but is not limited thereto.

The reflection assistance layer 130 may be disposed on the third sub electrode 121c.

That is, the third sub electrode 121c may be disposed between the second sub electrode 121b including a reflective conductive material and the reflection assistance layer 130.

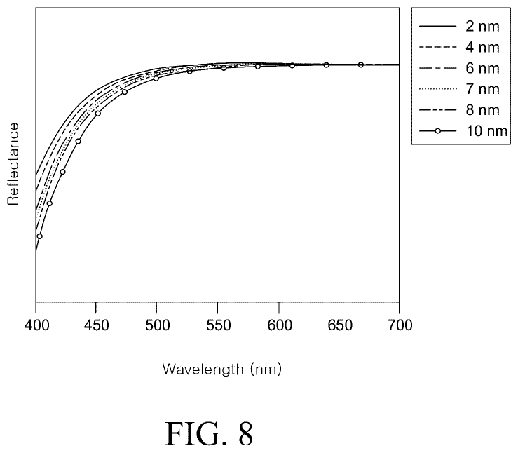

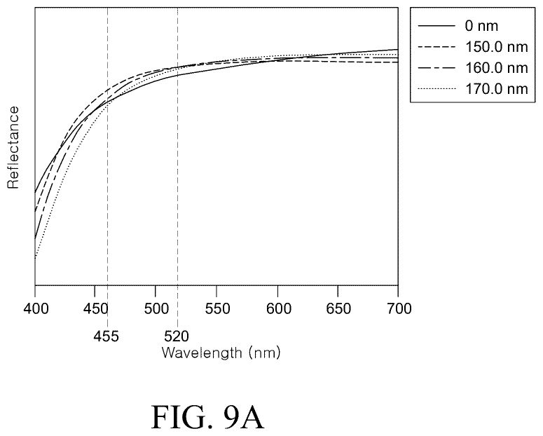

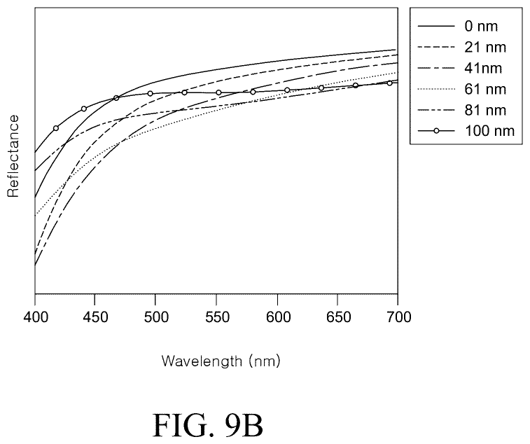

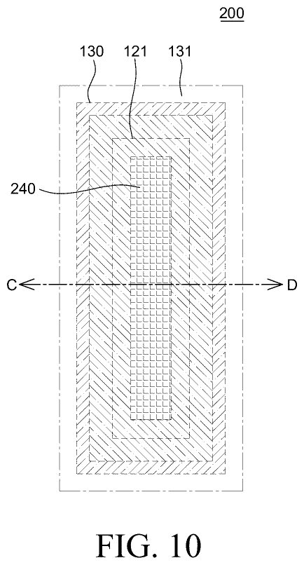

An amount of light reflected by the second sub electrode 121b may vary depending on a thickness of the third sub electrode 121c disposed between the second sub electrode 121b and the reflection assistance layer 130, which will be reviewed with reference to FIG. 8. Further, the thickness H of the reflection assistance layer 130 disposed on the third sub electrode 121c may vary so that the color reproductivity and the luminance of the display device may be simultaneously improved by adjusting the thickness, which will be reviewed with reference to FIG. 9.

FIG. 8 is a graph obtained by measuring a reflectance of a second sub electrode according to a thickness of a third sub electrode.

In FIG. 8, a structure of the first electrode 121 and the reflection assistance layer 130 used for measuring a reflectance of the second sub electrode 120b is the same as the structure illustrated in FIG. 7.

Referring to FIG. 8, it is understood that when the reflectance of the second sub electrode 121b is measured by adjusting the thickness of the third sub electrode 121c in the range of 2 nm to 10 nm, the larger the thickness of the third sub electrode 121c, the worse the reflectance of the second sub electrode 121b.

A thickness of the third sub electrode 121c of the first electrode 121 of the display device 100 according to the present disclosure may be 6 nm to 10 nm.

When the thickness of the third sub electrode 121c is small than 6 nm, an amount of light which reaches the second sub electrode 121b is increased, but the resistance of the third sub electrode 121c may be increased.

When the thickness of third sub electrode 121c exceeds 10 nm, an amount of light which reaches the second sub electrode 121b is reduced to reduce an amount of light reflected by the second sub electrode 121b and reduce an amount of light which is extracted to the outside of the display device 100. Accordingly, the front and side luminance characteristics may be degraded.

The thickness of the third sub pixel 121c of the first electrode 121 included in the display device 100 according to the example embodiment of the present disclosure is 6 nm to 10 nm so that an amount of light which reaches the second sub electrode 121b with an appropriate resistance for driving the light emitting diode ED may be increased.

FIGS. 9A and 9B are graphs illustrating a reflectance for a wavelength according to a thickness of a reflection assistance layer disposed in an active area of a display device according to an example embodiment of the present disclosure.

First, referring to FIG. 9A, it is understood that when reflection assistance layers 130 with various thicknesses are disposed on the first electrode 121 of the light emitting diode ED with a structure of FIG. 7, as compared with a structure in which the reflection assistance layer is not disposed (see a graph of a reflection assistance layer of 0 nm in FIG. 9A), the reflectance in a visible wavelength band is high.

Specifically, when the thickness of the reflection assistance layer 130 is 110 nm to 170 nm or smaller, the reflectance is high in the wavelength band of 455 nm to 520 nm.

Further, referring to FIG. 9B, it is understood that when the thickness of the reflectance assistance layer 130 is 100 nm or smaller, as compared with the structure in which the reflection assistance layer is not disposed (see a graph of a reflectance assistance layer of 0 nm in FIG. 9B), the reflectance in a visible wavelength band is low. In other words, when the thickness of the reflection assistance layer 130 is 100 nm or smaller, the light extraction efficiency of the display device may be decreased.

In the display device 100 according to the example embodiment of the present disclosure, the thickness of the reflection assistance layer 130 is 110 nm to 170 nm or smaller, to allow light in the wavelength range area of 455 nm to 520 nm to reach the first electrode 121. Therefore, the color reproductivity may be improved and the luminance is increased to reduce the power consumption.

FIG. 10 is a plan view schematically illustrating one sub pixel structure disposed in an active area of a display device according to another example embodiment of the present disclosure.

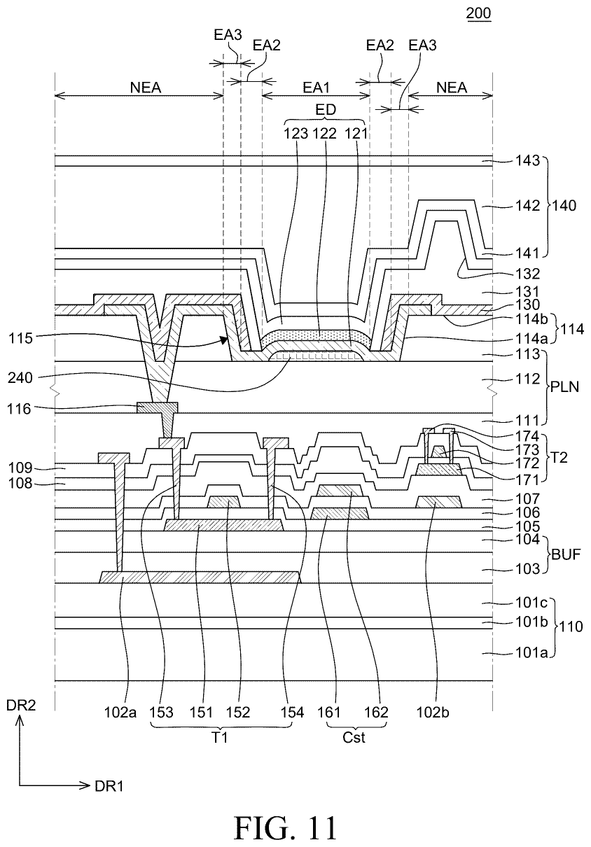

FIG. 11 is a cross-sectional view taken along the line C-D of FIG. 10.

As compared with the display device 100 of FIGS. 3 and 4, a display device 200 of FIGS. 10 and 11 has a structure in which a structure 240 is disposed in an opening of a third planarization layer 113 and a surface shape of a configuration disposed on the structure 240 is different, but the other configurations are substantially the same. Therefore, a redundant description will be omitted.

The structure 240 disposed in the concave portion 115 of the third planarization layer 113 may overlap a first emission area EA1.

The structure 240 may be disposed to be spaced apart from the reflection assistance layer 130.

In the cross-section view, a part of a top surface of the structure 240 may extend to a first direction DR1 and the other part of the top surface of the structure 240 may extend between the first direction DR1 and a second direction DR2 intersecting the first direction DR1. Here, the first direction DR1 may be a direction perpendicular to a direction in which a first buffer layer BUF is laminated on the substrate 110 and the second direction DR2 may be a direction which is the same as the direction in which the first buffer layer BUF is disposed on the substrate 110.

Specifically, a center area of the top surface of the structure 240 may extend in the first direction DR1 and an edge area of the top surface of the structure 240 may extend in a direction between the first direction DR1 and the second direction DR2. Here, a top surface located in an edge of the top surface of the structure 240 may extend in the form of a curved line or a straight line.

A first electrode 121, an organic layer 122, and a second electrode 123 of the light emitting diode ED disposed on the structure 240 may be formed along a surface shape of the structure 240 in the concave portion 115 of the third planarization layer 113. Further, the first encapsulation layer 141 may also be formed along the surface shape of the structure 240 in the concave portion 115 of the third planarization layer 113.

Specifically, in an area in which a top surface of the structure 240 extends in the first direction DR1, top surfaces of the first electrode 121, the organic layer 122, the second electrode 123, and the first encapsulation layer 141 may also extend in the first direction DR1.

Further, in an area in which a top surface of the structure 240 extends in the direction between the first direction DR1 and the second direction DR2, top surfaces of the first electrode 121, the organic layer 122, the second electrode 123, and the first encapsulation layer 141 may also extend in the direction between the first direction DR1 and the second direction DR2.

As described above, the edge (or the side surface) of the structure 240 extends in the direction between the first direction DR1 and the second direction DR2 to change a path to allow light which is not released to the front surface of the display device 100, among light emitted from the light emitting diode ED, to reach the reflection assistance layer 130 and the first electrode 121. Therefore, the light which is trapped in the display device 100 is released to the outside of the display device 100 to increase the front luminance of the display device 100.

A height H1 of the structure 240 may be smaller than a height H2 of the third planarization layer 113. Accordingly, a part of light emitted from the light emitting diode ED disposed on the structure 240 reaches the reflection assistance layer 130 disposed on the inclined portion 114a of the protruding portion 114 of the third planarization layer 113 and the first electrode 121 to be released to the outside of the display device 100.

Even though in FIGS. 10 and 11, a structure in which the structure 240 overlaps a part of the first emission area EA1 is illustrated, the present disclosure is not limited thereto. For example, the structure 240 may overlap the entire first emission area EA1 or overlap the entire first emission area EA1 and at least a part of the second emission area EA2.

When the structure 240 overlaps at least a part of the second emission area EA2, the structure 240 may overlap a part of the reflection assistance layer 130 and a part of the bank 131.

In the display device 200 according to another example embodiment of the present disclosure, the first electrode 121 of the light emitting diode ED disposed on a part of the concave portion 115 and the protruding portion 114 of the third planarization layer 113 improves the light extraction efficiency of the display device 200. Further, the reflection assistance layer 130 which overlaps an edge of the first electrode 121 increases an amount of light which is reflected from the first electrode 121 to be released to the outside of the display device 200. As a result, a light extraction efficiency for front and side surfaces of the display device 200 may be further improved.

Further, the display device 200 according to another example embodiment of the present disclosure releases light which is trapped in the display device 200 to the outside of the display device 200 through at least one structure 240 disposed in the concave portion 115, thereby improving the front luminance characteristic of the display device 200.

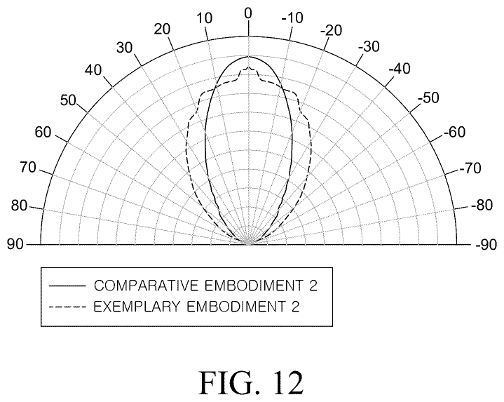

FIG. 12 is a graph comparing a viewing angle characteristic of display devices according to Comparative Embodiment 2 and Example Embodiment 2.

A display device according to Comparative Embodiment 2 is a general display device. Specifically, the display device according to Comparative Embodiment 2 has a structure in which a light emitting diode is disposed on a planarization layer with a flat top surface. The display device according to Example Embodiment 2 is a display device illustrated in FIGS. 10 and 11.

Referring to FIG. 12, it is understood that a viewing angle of the display device according to Example Embodiment 2 is improved more than a viewing angle of the display device according to Comparative Embodiment 2.

In other words, in the case of the display device according to Comparative Embodiment 2, when it is viewed from the side, the luminance is degraded, but in the case of the display device according to Example Embodiment 2, even though it is viewed from the side, the viewing is possible with a high luminance without increasing the power consumption.

In the meantime, in FIGS. 10 to 12, a structure in which one structure 240 is disposed in the concave portion 115 of the third planarization layer 113 has been illustrated, but the present disclosure is not limited thereto.

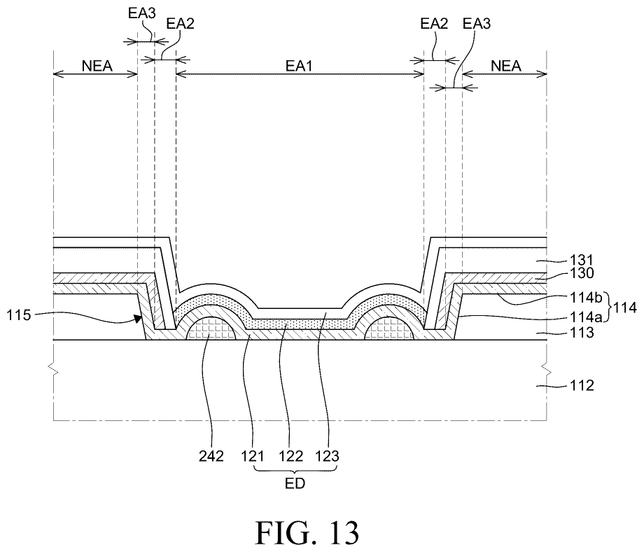

Various positions and shapes of the structure 240 will be reviewed with reference to FIGS. 13 to 15 as follows.

FIGS. 13 to 15 are schematic cross-sectional views illustrating a position and a shape of a structure which overlaps at least a part of a concave portion of a third planarization layer.

As compared with the display device of FIG. 11, in the display device of FIGS. 13 to 15, the number of structures, a position and a shape are different, but the other components are substantially the same so that a redundant description will be omitted.

Referring to FIGS. 13 to 15, the plurality of structures 240 and 242 is spaced apart from each other to be disposed. The light emitting diode ED may be disposed along the surface shape of the plurality of structures 240 and 242 which is spaced apart from each other. Therefore, a surface area of the light emitting diode ED may be increased.

The plurality of structures 240 and 242 may have various shapes. For example, at least some structure 242 may be semicircular in cross section, but is not limited thereto, and at least some structure 242 may be semi-elliptical shape.

Further, the other structure 240 may have the same shape as the structure 240 illustrated in FIG. 11.

Hereinafter, for the convenience of description, the reference numeral 240 denotes a first structure and the reference numeral 242 denotes a second structure.

The plurality of structures 240 and 242 may be disposed in various positions in an area in the concave portion 115 of the third planarization layer 113.

The plurality of structures 240 and 242 may be disposed in the first emission area EA1. However, the position of the plurality of structures 240 and 242 is not limited thereto and at least one of the plurality of structures 240 and 242 may overlap at least a part of the second emission area EA2.

As illustrated in FIG. 13, the plurality of second structures 242 may be disposed to be adjacent to an edge of the concave portion 115 of the third planarization layer 113. In other words, the plurality of second structures 242 may not be disposed in a center area of the concave portion 115 of the third planarization layer 113.

The plurality of second structures 242 is located in the edge of the concave portion 115 of the third planarization layer 113 to serve to allow some of light emitted from the light emitting diode ED to reach the reflection assistance layer 130 disposed on the inclined portion 114a of the third planarization layer 113 and the first electrode 121. Therefore, an amount of light which is emitted to the lateral direction of the display device 100 is increased to increase the side luminance of the display device 100.

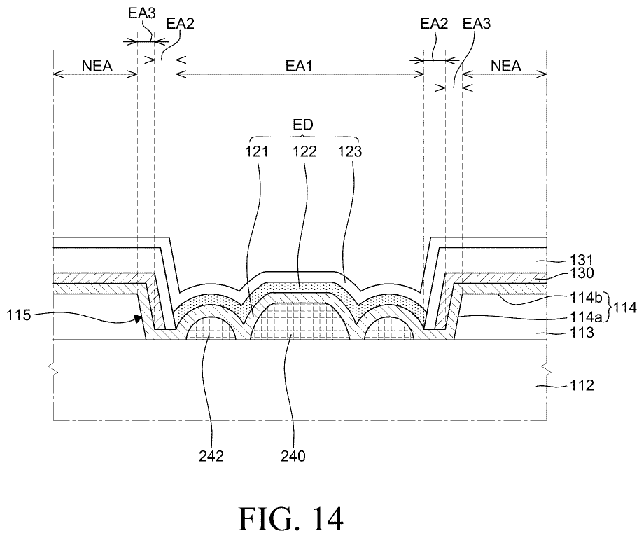

Further, as illustrated in FIG. 14, the plurality of second structures 242 is disposed in the edge of the concave portion 115 of the third planarization layer 113. When one first structure 240 is disposed in the center area of the concave portion 115 of the third planarization layer 113, the side luminance may be further improved by the plurality of second structures 242 disposed in the edge of the concave portion 115 of the third planarization layer 113 and the first structure 240.

Even though in FIG. 14, a structure in which a height of the second structure 242 is different from a height of the first structure 240 has been illustrated, the present disclosure is not limited thereto. The height of the second structure 242 and the height of the first structure 240 may be the same and the height of the first structure 240 may be smaller than the height of the second structure 242.

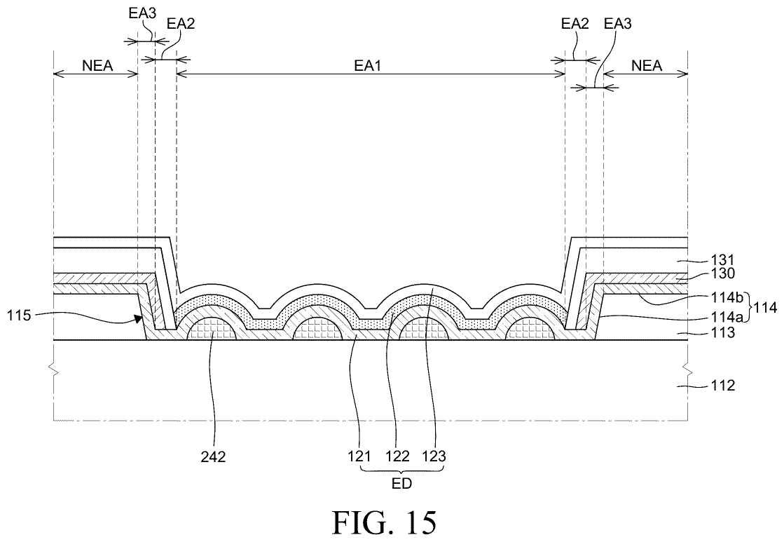

Further, as illustrated in FIG. 15, the plurality of second structures 242 may be disposed in the edge and the center area of the concave portion 115 of the third planarization layer 113 and allow some of light emitted from the light emitting diode ED to reach the reflection assistance layer 130 disposed on the inclined portion 114a of the third planarization layer 113 and the first electrode 121 not only in the edge of the concave portion 115 of the third planarization layer 113, but also in the center area.

Therefore, an amount of light which is emitted to the lateral direction of the display device is increased to increase the side luminance of the display device 100.

Here, the reflection assistance layer 130 disposed on the inclined portion 114a of the third planarization layer 113 serves to increase an amount of light which reaches the first electrode 121 disposed on the inclined portion 114a of the third planarization layer 113 and emit light which reaches the first electrode 121 may be released to the front and side directions of the display device 100.

Accordingly, the front luminance and the side luminance of the display device may be simultaneously improved and as the side luminance is increased, the spot may not be visible when the display device is seen from the side surface.

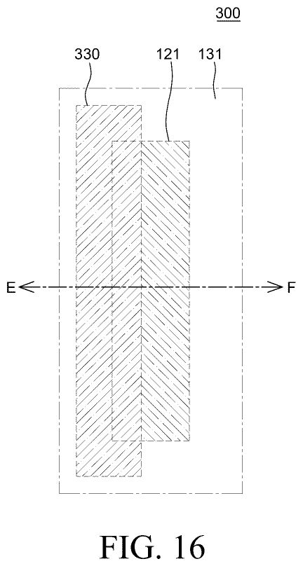

FIG. 16 is a plan view schematically illustrating one sub pixel structure disposed in an active area of a display device according to still another example embodiment of the present disclosure.

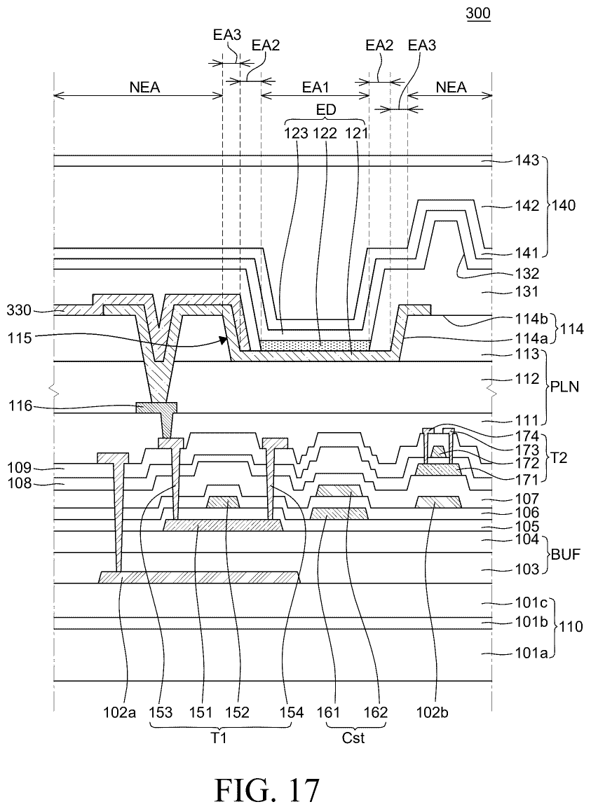

FIG. 17 is a cross-sectional view taken along the line E-F of FIG. 16.

As compared with the display device of FIGS. 3 and 4, in a display device 300 of FIGS. 16 and 17, at least one reflection assistance layer 330 is disposed only in a part of an edge of the opening, but the other components are substantially the same so that a redundant description will be omitted.

A reflection assistance layer 130 may be disposed on a part of the third planarization layer 113 and a part of the first electrode 121.

In the plan view, the reflection assistance layer 130 may be disposed so as to cover at least one side surface of the first electrode 121. In this case, the reflection assistance layer 130 may be disposed on at least one side surface of the concave portion 115.

For example, when a planar shape of the first electrode 121 is a quadrangular shape, the reflection assistance layer 130 may be disposed so as to enclose one or three side surfaces of the first electrode 121. At this time, the reflection assistance layer 130 may be disposed in a part of the concave portion 115 of the third planarization layer 113 and may be disposed on a part of the inclined portion 114a of the third planarization layer 113.

As described above, the reflection assistance layer 130 is disposed so as to cover a part of the side surface of the first electrode 121 so that a viewing angle characteristic may be improved in a specific position of the display device 300.

For example, the reflection assistance layer 130 disposed in the sub pixel SP of the second area A2 of FIG. 1 is disposed so as to cover a part of the side surface of the first electrode 121 to adjust the viewing angle luminance. Therefore, a viewer who looks at the display device 100 in the front direction may feel immersed in the screen of the second area A2.

However, this is just an example and the structure of FIGS. 16 and 17 may be included in a part or all the sub pixel SP included in the display device 300.

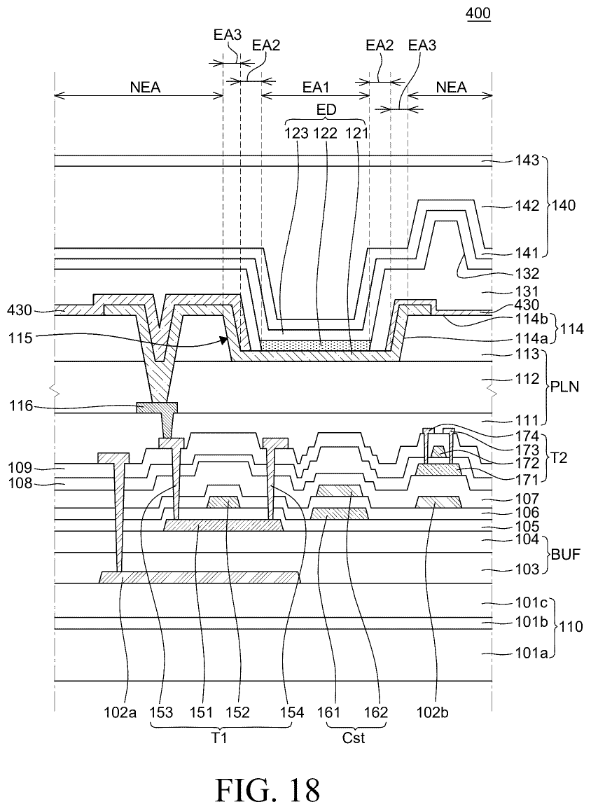

FIG. 18 is a cross-sectional view illustrating one sub pixel structure disposed in an active area of a display device according to still another example embodiment of the present disclosure.

As compared with the display device of FIG. 4, in a display device 400 of FIG. 18, a reflection assistance layer applied to at least one sub pixel has a thickness which varies in every area, but the other components are substantially the same so that a redundant description will be omitted.

The first electrode 121 of the light emitting diode ED may be disposed in the concave portion 115 of the third planarization layer 113, the entire inclined portion 114a and a part of the flat portion 114b of the protruding portion 114 of the third planarization layer 113.

A reflection assistance layer 430a may be disposed on a part of the top surface of the first electrode 121 and at least a part of the flat portion 114b of the protruding portion 114 of the third planarization layer 113.

The reflection assistance layer 430a may be disposed so as to enclose an edge of the first electrode 121.

The reflection assistance layer 430a may have an area having different thicknesses in one sub pixel.

For example, a sub pixel in which the reflection assistance layer 430a is disposed is disposed in a second area A2 of FIG. 1 and is biased to the left with respect to the viewer's viewpoint, on the cross-section, a thickness of the reflection assistance layer 430a including an area overlapping the first transistor T1 may be larger than a thickness of the reflection assistance layer 430a including an area overlapping the second transistor T2.

However, this is just an example and at least two parts in which the thickness of the reflection assistance layer 430a is different are enough in one sub pixel.

As described above, a thickness of the reflection assistance layer 430a is adjusted even in one sub pixel to adjust the viewing angle luminance to a fine level.

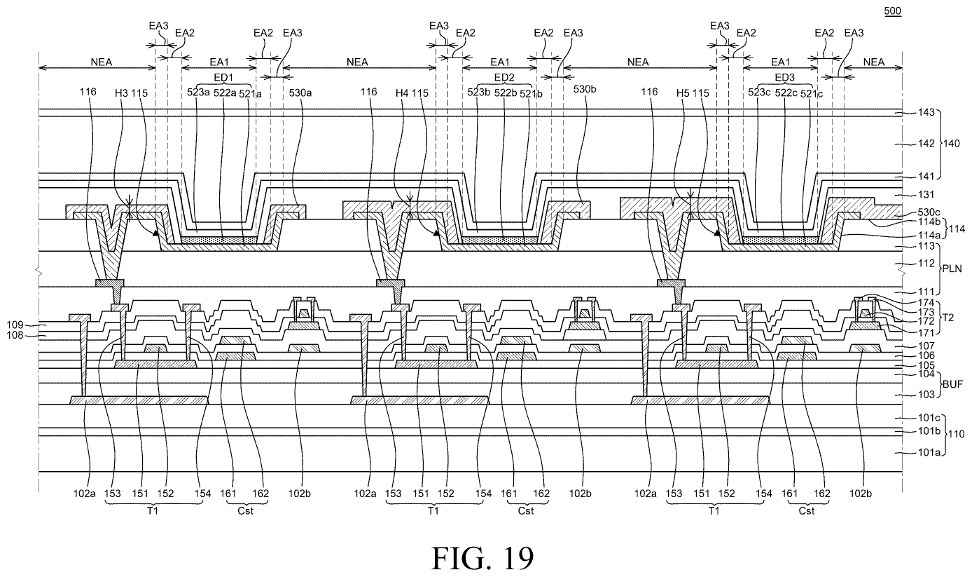

FIG. 19 is a cross-sectional view illustrating a plurality of sub pixel structures disposed in an active area of a display device according to still another example embodiment of the present disclosure.

A display device 500 of FIG. 19 has a structure in which reflection assistance layers 530a, 530b, and 530c are disposed in at least three sub pixels SP1, SP2, and SP3, but the other components are substantially the same as the display device of FIG. 4, so that a redundant description will be omitted.

The display device 500 may include a first sub pixel SP1, a second sub pixel SP2, and a third sub pixel SP3. The first sub pixel SP1 may include a first light emitting diode ED1 which emits first light, the second sub pixel SP2 may include a second light emitting diode ED2 which emits second light having a color different from the first light, and the third sub pixel SP3 may include a third light emitting diode ED3 which emits third light having a color different from the first light and second light.

The first light emitting diode ED1 may include a first electrode 521a, an organic layer 522a, and a second electrode 523a.

The second light emitting diode ED2 may include a first electrode 521b, an organic layer 522b, and a second electrode 523b.

The third light emitting diode ED3 may include a first electrode 521c, an organic layer 522c, and a second electrode 523c.

The first light emitting diode ED1 may be a light emitting diode which emits blue light, the second light emitting diode ED2 may be a light emitting diode which emits green light, and the third light emitting diode ED3 may be a light emitting diode which emits red light, but the present disclosure is not limited thereto.

The first reflection assistance layer 530a may be disposed on a part of the first electrode 521a of the first light emitting diode ED1 and a part of the third planarization layer 113.

The second reflection assistance layer 530b may be disposed on a part of the first electrode 521b of the second light emitting diode ED2 and a part of the third planarization layer 113.

The third reflection assistance layer 530c may be disposed on a part of the first electrode 521c of the third light emitting diode ED3 and a part of the third planarization layer 113.

The first reflection assistance layer 530a may be disposed so as to cover an edge of the first electrode 521a of the first light emitting diode ED1 and may be disposed to extend to a part of the top surface of the third planarization layer 113.

Further, the first reflection assistance layer 530a may overlap a partial area of the concave portion 115 of the third planarization layer 113.

The second reflection assistance layer 530b may be disposed so as to cover an edge of the first electrode 521b of the second light emitting diode ED2 and may be disposed to extend to a part of the top surface of the third planarization layer 113.

Further, the second reflection assistance layer 530b may overlap a partial area of the concave portion 115 of the third planarization layer 113.

The third reflection assistance layer 530c may be disposed so as to cover an edge of the first electrode 521c of the third light emitting diode ED3 and may be disposed to extend to a part of the top surface of the third planarization layer 113.

Further, the third reflection assistance layer 530c may overlap a partial area of the concave portion 115 of the third planarization layer 113.

Each of the first reflection assistance layer 530a, the second reflection assistance layer 530b, and the third reflection assistance layer 530c may overlap the second emission area EA2 and the third emission area EA3 of each sub pixel SP1, SP2, SP3.

The first reflection assistance layer 530a may be disposed to be spaced apart from the organic layer 522a of the first light emitting diode ED1 disposed in the concave portion 115 of the third planarization layer 113. The second reflection assistance layer 530b may be disposed to be spaced apart from the organic layer 522b of the second light emitting diode ED2 disposed in the concave portion 115 of the third planarization layer 113. The third reflection assistance layer 530c may be disposed to be spaced apart from the organic layer 522c of the third light emitting diode ED3 disposed in the concave portion 115 of the third planarization layer 113.

Thicknesses of the first reflection assistance layer 530a, the second reflection assistance layer 530b, and the third reflection assistance layer 530c may be different. For example, a thickness H5 of the third reflection assistance layer 530c may be larger than thicknesses H3 and H4 of the first and second reflection assistance layers 530a and 530b, and the thickness H4 of the second reflection assistance layer 530b may be larger than the thickness H3 of the first reflection assistance layer 530a.

Here, the thicknesses H3, H4, and H5 of the first to third reflection assistance layers 530a, 530b, and 530c may refer to a shortest length in the same direction as the direction in which the first buffer layer BUF is laminated on the substrate 110.

For example, a thickness of the first reflection assistance layer 530a may be 120 nm to 140 nm, a thickness of the second reflection assistance layer 530b may be 140 nm to 160 nm, and a thickness of the third reflection assistance layer 530c may be 180 nm to 200 nm.

That is, in the sub pixels SP1, SP2, and SP3 which emit light in different wavelength bands, reflection assistance layers 530a, 530b, and 530c having different thicknesses may be disposed.

Specifically, when different light is emitted from the first to third sub pixels SP1, SP2, and SP3, reflection assistance layers 530a, 530b, and 530c which increase an amount of light which reaches the reflection electrode (for example, the second sub electrode) included in the first electrodes 521a, 521b, and 521c disposed in the first to third sub pixels SP1, SP2, and SP3 may have different thicknesses.

The first to third sub pixels SP1, SP2, and SP3 may be disposed in the first area A1 illustrated in FIG. 1 and may also be disposed in the second area A2.

In a display device 500 according to still another example embodiment of the present disclosure illustrated in FIG. 19, first to third reflection assistance layers 530a, 530b, and 530b disposed in the first to third sub pixels SP1, SP2, and SP3 have different thicknesses to optimize an amount of light which reaches the first electrodes 521a, 521b, and 521c disposed in the first to third sub pixels SP1, SP2, and SP3. By doing this, even though light in different wavelength bands is emitted to the outside of the display device 500, the color reproductivity may be improved and the front luminance and the side luminance may be improved.

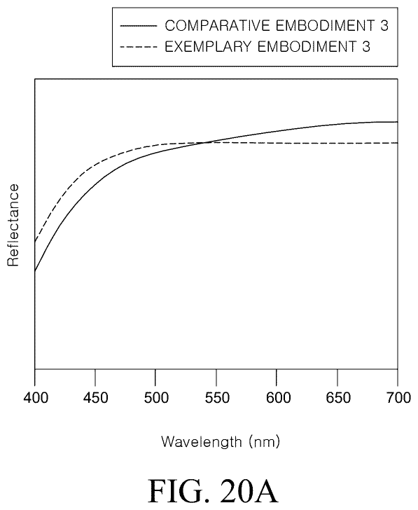

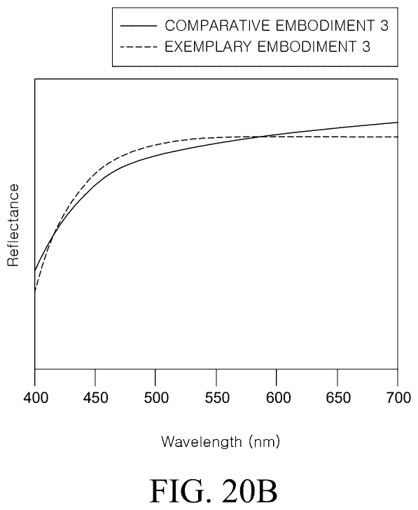

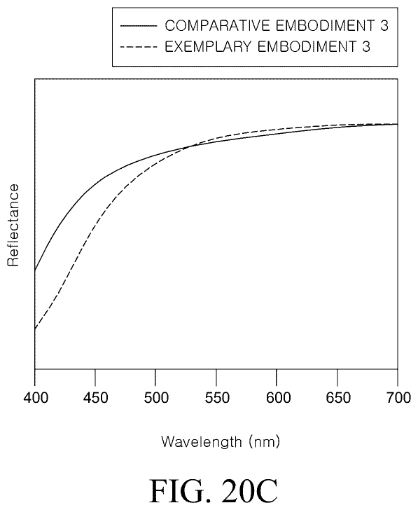

This effect will be specifically reviewed with reference to FIGS. 20A to 20C as follows.

FIG. 20A is a graph comparing a reflectance of a blue wavelength band of a display device according to Comparative Embodiment 3 and a reflectance of a blue wavelength band of a display device according to Example Embodiment 3.

FIG. 20B is a graph comparing a reflectance of a green wavelength band of a display device according to Comparative Embodiment 3 and a reflectance of a green wavelength band of a display device according to Example Embodiment 3.

FIG. 20C is a graph comparing a reflectance of a red wavelength band of a display device according to Comparative Embodiment 3 and a reflectance of a red wavelength band of a display device according to Example Embodiment 3.

A display device according to Comparative Embodiment 3 is a general display device. Specifically, the display device according to Comparative Embodiment 3 has a structure in which a light emitting diode is disposed on a planarization layer with a flat top surface. The display device according to Example Embodiment 3 is a display device illustrated in FIG. 17.

Referring to FIGS. 20A to 20C, it is understood that a reflectance of the display device according to Example Embodiment 3 is higher than a reflectance of the display device according to Comparative Embodiment 3 in blue, green, and red wavelength bands.

In the display device according to Example Embodiment 3, the first reflection assistance layer 530a has a thickness of 120 nm to 140 nm so that a large amount of light in a blue wavelength band reaches the first electrode 521a of the first light emitting diode ED1 to improve the color reproductivity for blue and increase the luminance.

Further, the second reflection assistance layer 530b has a thickness of 140 nm to 160 nm so that a large amount of light in a green wavelength band reaches the first electrode 521b of the second light emitting diode ED2 to improve the color reproductivity for green and increase the luminance.

Further, the third reflection assistance layer 530c has a thickness of 180 nm to 200 nm so that a large amount of light in a green wavelength band reaches the first electrode 521c of the third light emitting diode ED3 to improve the color reproductivity for green and increase the luminance.

When the reflection assistance layer having the same thickness is applied to the sub pixel which emits light of different colors, in the sub pixel which emits light in a specific wavelength band, the color reproductivity may be improved, but the luminance may be degraded.

For example, when in the third sub pixel SP3 including a third light emitting diode ED3 which emits red light, the third reflection assistance layer 530c having the same thickness as the thickness of the first and second reflection assistance layers 530a and 530b disposed in the first and second sub pixels SP1 and SP2 is disposed, the color reproductivity for the red may be improved, but the luminance may be degraded.

However, like the display device according to Example Embodiment 3, the first to third reflection assistance layers 530a, 530b, and 530c disposed in the first to third sub pixels SP1, SP2, and SP3 are configured to have different thicknesses, to improve the color reproductivity of the first to third sub pixels SP1, SP2, and SP3 and improve the luminance.

The example embodiments of the present disclosure can also be described as follows:

According to an aspect of the present disclosure, there is provided a display device. The display device includes a substrate and a plurality of sub pixels. The display device further includes a planarization layer which is disposed on the substrate and includes a concave portion and a protruding portion. The display device further includes a first electrode disposed so as to cover the concave portion and a part of the protruding portion. The display device further includes a reflection assistance layer which is disposed in a part of the concave portion and covers at least a part of an edge of the first electrode. The display device further includes a bank which is disposed on a part of a top surface of the first electrode and is disposed on the reflection assistance layer. The display device further includes an organic layer disposed on the top surface of the first electrode. The display device further includes a second electrode disposed on the bank and the organic layer.

The bank may cover a top surface and a side surface of the reflection assistance layer.

The reflection assistance layer may be disposed in a partial area of the concave portion, an inclined portion of the protruding portion, and a part of a flat portion of the protruding portion.

The reflection assistance layer may not overlap the part of the top surface of the first electrode disposed in the concave portion.

In an area in which the bank exposes the top surface of the first electrode, the reflection assistance layer may not overlap the first electrode.

The reflection assistance layer and the organic layer may be spaced apart from each other in the concave portion.

Th bank may be disposed between the reflection assistance layer and the organic layer in the concave portion.

The display device may include at least one structure disposed on the planarization layer and the at least one structure may be disposed in the concave portion.

The first electrode may be disposed on the at least one structure and the at least one structure does not overlap the bank.

The at least one structure may have an elliptical shape or a semi-elliptical shape on a cross-section and a part of a top surface of the at least one structure may extend in a first direction on the cross-section and the other part may extend in a second direction which is different from the first direction.

The reflection assistance layer may be disposed in at least one sub pixel, among the plurality of sub pixels and the reflection assistance layer may be disposed on the part of the edge of the first electrode.

The substrate may include a curved area and a flat area and in the plurality of sub pixels disposed in the curved area, the reflection assistance layer may be disposed on the part of the edge of the first electrode.

The substrate may include a curved area and a flat area and in the plurality of sub pixels disposed in the curved area, the reflection assistance layer may include at least two or more parts having different thicknesses.

The plurality of sub pixels may include a first sub pixel, a second sub pixel which emits light having a color which is different from that of the first sub pixel, and a third sub pixel which emits light having a color which is different from that of the second sub pixel, the reflection assistance layer may include a first reflection assistance layer, a second reflection assistance layer, and a third reflection assistance layer, the first reflection assistance layer may be disposed in the first sub pixel, the second reflection assistance layer may be disposed in the second sub pixel, the third reflection assistance layer may be disposed in the third sub pixel, anda thickness of the first reflection assistance layer, a thickness of the second reflection assistance layer, and a thickness of the third reflection assistance layer may be different from each other.

The first sub pixel may emit blue light, the second sub pixel emits green light, the third sub pixel emits red light, and the thickness of the third reflection assistance layer may be larger than the thickness of the first reflection assistance layer and the thickness of the second reflection assistance layer and the thickness of the second reflection assistance layer may be larger than the thickness of the first reflection assistance layer.

The thickness of the first reflection assistance layer may be 120 to 140 nm, the thickness of the second reflection assistance layer may be 140 nm to 160 nm, and the thickness of the third reflection assistance layer may be 180 nm to 200 nm.

At least one sub pixel, among the plurality of sub pixels, may include a first emission area, a second emission area which encloses the first emission area, and a third emission area which encloses the second emission area and the reflection assistance layer may be disposed in a part of the second emission area and the third emission area.

The reflection assistance layer may include magnesium fluoride (MgF₂).

The first electrode may include a first sub electrode disposed on the planarization layer, a second sub electrode disposed on the first sub electrode, and a third sub electrode disposed on the second sub electrode and each of the third sub electrodes may include at least one of indium tin oxide (ITO), indium zinc oxide (IZO), and indium gallium zinc oxide (IGZO) and a thickness of the third sub electrode may be 6 nm to 10 nm.

According to another aspect of the present disclosure, there is provided a display device. The display device includes a substrate and a plurality of sub pixels. The display device further includes a planarization layer which is disposed on the substrate and includes a concave portion and a protruding portion. The display device further includes a first electrode disposed so as to cover the concave portion and a part of the protruding portion. The display device further includes a reflection assistance layer which covers at least a part of an edge of the first electrode. The display device further includes a bank which is disposed on a part of a top surface of the first electrode and is disposed on the reflection assistance layer. The display device further includes an organic layer disposed on the top surface of the first electrode. The display device further includes a second electrode disposed on the bank and the organic layer. Further, at least one of the plurality of sub pixels includes a first emission area, a second emission area which encloses the first emission area, and a third emission area which encloses the second emission area and the reflection assistance layer is disposed in at least a part of each of the second emission area and the third emission area.

The reflection assistance layer may be disposed in a partial area of the concave portion, an inclined portion of the protruding portion, and a part of a flat portion of the protruding portion.

The reflection assistance layer and the organic layer may be spaced apart from each other in the concave portion.

The reflection assistance layer may be disposed in at least one sub pixel, among the plurality of sub pixels and the reflection assistance layer may be disposed on the part of the edge of the first electrode.

The plurality of sub pixels may include a first sub pixel, a second sub pixel which emits light having a color which is different from that of the first sub pixel, and a third sub pixel which emits light having a color which is different from that of the second sub pixel, the reflection assistance layer may include a first reflection assistance layer, a second reflection assistance layer, and a third reflection assistance layer, the first reflection assistance layer may be disposed in the first sub pixel, the second reflection assistance layer may be disposed in the second sub pixel, the third reflection assistance layer may be disposed in the third sub pixel, and a thickness of the first reflection assistance layer, a thickness of the second reflection assistance layer, and a thickness of the third reflection assistance layer may be different from each other.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a plurality of sub pixels;
a planarization layer which is disposed on the substrate and includes a concave portion and a protruding portion;
a first electrode disposed so as to cover the concave portion and a part of the protruding portion;
a reflection assistance layer which is disposed in a part of the concave portion and covers at least a part of an edge of the first electrode;
a bank which is disposed on a part of a top surface of the first electrode and is disposed on the reflection assistance layer;
an organic layer disposed on the top surface of the first electrode; and
a second electrode disposed on the bank and the organic layer.

2. The display device according to claim 1, wherein the bank covers a top surface and a side surface of the reflection assistance layer.

3. The display device according to claim 1, wherein the reflection assistance layer is disposed in a partial area of the concave portion, an inclined portion of the protruding portion, and a part of a flat portion of the protruding portion.

4. The display device according to claim 1, wherein the reflection assistance layer does not overlap the part of the top surface of the first electrode disposed in the concave portion.

5. The display device according to claim 1, wherein in an area in which the bank exposes the top surface of the first electrode, the reflection assistance layer does not overlap the first electrode.

6. The display device according to claim 1, wherein the reflection assistance layer and the organic layer are spaced apart from each other in the concave portion.

7. The display device according to claim 1, wherein the bank is disposed between the reflection assistance layer and the organic layer in the concave portion.

8. The display device according to claim 1, further comprising:
at least one structure disposed on the planarization layer,
wherein the at least one structure is disposed in the concave portion.

9. The display device according to claim 8, wherein the first electrode is disposed on the at least one structure, and the at least one structure does not overlap the bank.

10. The display device according to claim 9, wherein the at least one structure has an elliptical shape or a semi-elliptical shape on a cross-section, wherein a part of a top surface of the at least one structure extends in a first direction on the cross-section, and wherein the other part of the top surface of the at least one structure extends in a second direction which is different from the first direction.

11. The display device according to claim 1, wherein the reflection assistance layer is disposed in at least one sub pixel, among the plurality of sub pixels, and the reflection assistance layer is disposed on the part of the edge of the first electrode.

12. The display device according to claim 1, comprising a curved area and a flat area, wherein in the plurality of sub pixels disposed in the curved area, the reflection assistance layer is disposed on the part of the edge of the first electrode.

13. The display device according to claim 1, comprising a curved area and a flat area, wherein in the plurality of sub pixels disposed in the curved area, the reflection assistance layer includes at least two or more parts having different thicknesses.

14. The display device according to claim 1, wherein the plurality of sub pixels includes a first sub pixel, a second sub pixel configured to emit light having a color which is different from a color of the first sub pixel, and a third sub pixel configured to emit light having a color which is different from the color of the second sub pixel,
wherein the reflection assistance layer includes a first reflection assistance layer, a second reflection assistance layer, and a third reflection assistance layer,
wherein the first reflection assistance layer is disposed in the first sub pixel, the second reflection assistance layer is disposed in the second sub pixel, and the third reflection assistance layer is disposed in the third sub pixel, and
wherein a thickness of the first reflection assistance layer, a thickness of the second reflection assistance layer, and a thickness of the third reflection assistance layer are different from each other.

15. The display device according to claim 14, wherein the first sub pixel is configured to emit blue light, the second sub pixel configured to emit green light, the third sub pixel configured to emit red light, and
wherein the thickness of the third reflection assistance layer is greater than each of the thickness of the first reflection assistance layer and the thickness of the second reflection assistance layer, and
wherein the thickness of the second reflection assistance layer is greater than the thickness of the first reflection assistance layer.

16. The display device according to claim 14, wherein the thickness of the first reflection assistance layer is 120 to 140 nm, the thickness of the second reflection assistance layer is 140 nm to 160 nm, and the thickness of the third reflection assistance layer is 180 nm to 200 nm.

17. The display device according to claim 1, wherein at least one sub pixel, among the plurality of sub pixels, includes a first emission area, a second emission area which encloses the first emission area, and a third emission area which encloses the second emission area, and
wherein the reflection assistance layer is disposed in a part of the second emission area and the third emission area.

18. The display device according to claim 1, wherein the reflection assistance layer includes magnesium fluoride (MgF₂).

19. The display device according to claim 1, wherein the first electrode includes a first sub electrode disposed on the planarization layer, a second sub electrode disposed on the first sub electrode, and a third sub electrode disposed on the second sub electrode,
wherein the third sub electrode includes at least one of indium tin oxide (ITO), indium zinc oxide (IZO), and indium gallium zinc oxide (IGZO), and
wherein a thickness of the third sub electrode is 6 nm to 10 nm.

20. A display device, comprising:
a substrate;
a plurality of sub pixels;
a planarization layer which is disposed on the substrate and includes a concave portion and a protruding portion;
a first electrode disposed so as to cover the concave portion and a part of the protruding portion;
a reflection assistance layer which covers at least a part of an edge of the first electrode;
a bank which is disposed on a part of a top surface of the first electrode and is disposed on the reflection assistance layer;
an organic layer disposed on the top surface of the first electrode; and
a second electrode disposed on the bank and the organic layer,
wherein at least one of the plurality of sub pixels includes a first emission area, a second emission area which encloses the first emission area, and a third emission area which encloses the second emission area, and
wherein the reflection assistance layer is disposed in at least a part of each of the second emission area and the third emission area.
